(19) United States
(12) Patent Application Publication
(10) Pub. No.: US 2019/0271910 A1
(43) Pub. Date: Sep. 5, 2019

(54) NANOPATTERNING OF PHASE CHANGE MATERIALS VIA HEATED PROBE

(71) Applicant: The Government of the United States of America, as represented by the Secretary of the Navy, Arlington, VA (US)

(72) Inventors: Laura Ruppalt, Alexandria, VA (US); Woo K. Lee, Vienna, VA (US); Paul E. Sheehan, Springfield, VA (US); Adrian Podpirka, Philadelphia, PA (US)

(21) Appl. No.: 16/419,273

(22) Filed: May 22, 2019

Related U.S. Application Data
(62) Division of application No. 15/430,725, filed on Feb. 13, 2017.
(60) Provisional application No. 62/298,069, filed on Feb. 22, 2016.

(51) Int. Cl. G03F 7/00

(52) U.S. Cl. CPC G03F 7/0002

(57) ABSTRACT

The present invention provides a method for creating patterns, with features down to the nanometer scale, in phase change materials using a heated probe. The heated probe contacts the phase change material thereby inducing a local phase change, resulting in a dramatic contrast in property—including electrical resistance, optical reflectance, and volume—relative to the uncontacted regions of the phase change material. The phase change material can be converted back to its original phase (i.e. the patterns can be erased) by appropriate thermal cycling.

### PRIORITY CLAIM

The present application is a divisional application of U.S. application Ser. No. 15/430,725, filed on Feb. 13, 2017 by Laura Ruppalt et al., entitled “NANOPATTERNING OF PHASE CHANGE MATERIALS VIA HEATED PROBE,” which was a non-provisional application claiming the benefit of U.S. Provisional Application No. 62/298,069, filed on Feb. 22, 2016 by Laura Ruppalt et al., entitled “NANOPATTERNING OF PHASE CHANGE MATERIALS VIA HEATED PROBE,” the entire contents of each are incorporated herein by reference.

### BACKGROUND OF THE INVENTION

### Field of the Invention

The present invention relates to creating patterns in phase change solids using a nanoscale heated probe.

### Description of the Prior Art

Phase change materials (PCMs) are solids which can be reversibly transitioned between multiple solid phases (for example, between amorphous and crystalline or between two different crystalline phases), typically through application of heat. Examples of PCMs include many chalcogenides (compounds containing elements from column VI of the Periodic Table), as well as some oxides, including VO₂. For many applications, different phases of these materials often exhibit very different physical properties. For instance, in many Te-containing chalcogenides, the amorphous phase is electrically insulating, optically absorptive, and less dense, while the crystalline phase is electrically conductive, optically reflective, and more dense. Chalcogenide-based PCMs have widely been utilized as the recording media in rewritable optical data storage devices (e.g. rewritable CDs and DVDs), where a laser is used to induce the amorphous-to-crystalline phase transition. Additionally, PCMs have more recently been examined as candidates for non-volatile electrical memory (i.e. Phase Change Memory), and are currently being researched for use in RF devices, hybrid metamaterial devices, and other applications.

Some applications benefit from local, nanoscale lithography of materials to fabricate minute patterns with distinct contrast from the surrounding field. The contrast required varies by application, but can include electrical (e.g. metal features within an insulating matrix), optical (e.g. reflective features within a transparent or absorptive field), volumetric (e.g. depressed features within a raised field), and chemical (e.g. etchable vs. etch-resistant) properties. The dramatic difference in property between the phases of PCMs makes them a promising material for applications that require such patterning. Previous methods utilized to induce localized crystallographic phase change include the use of electrically biased atomic force microscopy (AFM) tips (i.e. conductive AFM), AFM-based pressure-induced phase change (i.e. use of nanomechanical force microscopy—NFM), laser-based lithography or utilizing embedded heaters. In each of these cases, different drawbacks exist which would prevent the PCM patterning in certain applications or on certain substrates. Electrically biased tips use an electrical current to induce a transformation, requiring an electrically conducting buried layer or substrate, preventing patterning on insulating dielectric substrates. NFM requires hundreds of micronewtons of force to induce a phase change, which can cause abrasion to tips and erode pattern fidelity over time. Laser lithography often requires complex optical components, which are difficult to integrate. Embedded heaters require prior definition of the patterned area, preventing arbitrary in-situ changes in device design.

### BRIEF SUMMARY OF THE INVENTION

The aforementioned problems are overcome in the present invention which provides a method for creating nanometer patterns, with features down to the nanometer scale, in phase change solids—materials that demonstrate a thermally-induced phase transition—by use of a nanoscale heated probe. The method of the present invention uses a heated probe, such as an AFM tip, to create arbitrary nanoscale patterns on a PCM surface with significant electrical, optical, or topographic contrast, using simple piezo-electric control. The heated probe locally induces the phase change material to transform from its amorphous phase to its crystalline phase, resulting in a dramatic contrast in property—including electrical resistance, optical reflectance, and volume—relative to the unheated regions. In some cases, the material can be converted back to its amorphous phase (i.e. the patterns can be erased) by appropriate thermal cycling. This approach to patterning can be utilized for a variety of applications, including, but not limited to, creating adaptive circuits and devices, defining nanoscale lithographic patterns, defining nanoscale devices, developing rewritable circuitry.

Patterning PCMs via heated probe offers several advantages relative to other techniques. The nanoscale dimension of the probe allows extremely small feature sizes, and the pattern width and depth can be varied easily using a single probe through controlling the probe temperature and write-speed. Furthermore, the technique limits modification to the surface of the PCM, allowing materials of varying thickness and on arbitrary substrates to be patterned. Established techniques for multi-AFM-tip arrays can be exploited to increase scalability, simultaneously generating patterns across a large area in parallel.

Though nanoscale patterning of chalcogenide-based PCMS has previously been demonstrated, the reported means and modalities for patterning differ significantly from the present invention. Conductive AFM and NFM both use similar AFM probes, but have significant disadvantages in terms of limiting the material stacks that can be used and inducing probe damage. Neither makes use of direct heating of the nanoscale probe to transfer heat to the PCM surface. Laser lithography utilizes optical energy to locally heat the PCM surface and often requires complex optics for control and variation of pattern dimensions. Buried heaters prevent arbitrary patterning in situ.

These and other features and advantages of the invention, as well as the invention itself, will become better understood by reference to the following detailed description, appended claims, and accompanying drawings.

### BRIEF DESCRIPTION OF THE DRAWINGS

FIG. 1 is a diagram of the heated probe.

FIG. 2 shows patterning of a GeTe surface using the heated probe.

FIG. 3A shows XRD measurement of the as-deposited GeTe thin film as a function of temperature, from 35° C. to 325° C. Initial crystallization, as indicated by the emergence of diffraction peaks, begins near 180° C. FIG. 3B shows XRD scans of the as-deposited and annealed (at 325° C.) GeTe films taken at 35° C. The annealed film exhibits crystalline peaks related to the cubic Fm-3m space group (rock-salt structure).

FIG. 4 is a plot of electrical resistance as a function of temperature for as-deposited GeTe films. The arrows represent the direction of heating (cooling). The amorphous as-deposited film crystallizes near 185° C., as indicated by the precipitous drop in resistance, resulting in an amorphous/crystalline resistance ratio of ˜5×10⁶ near room temperature.

FIG. 5 shows the depth of ˜1 μm×1 μm crystalline squares vs. nominal AFM probe temperature used for patterning. Patterns were obtained by scanning the tip at a speed of 500 nm/s and rastering across each area for ˜20 minutes. Insets are topographic AFM images of the patterned regions.

FIG. 6A shows an AFM topograph of crystalline GeTe channels patterned at a nominal tip temperature of 700° C. with probe speeds as indicated. FIG. 6B shows the surface height profile along the line indicated in FIG. 6A. FIG. 6C shows the measured pattern depth and width of channels as a function of probe speed.

FIG. 7A is a bright-field transmission electron micrograph of focused ion beam-prepared cross-sectional lamella showing subsurface crystallization beneath lines patterned with nominal tip temperature of 6.83 mW at varying probe speeds, as indicated. FIG. 7B shows a higher magnification micrograph of separate region patterned at 6.83 mW and 100 nm/s showing extent of polycrystalline transformation.

FIG. 8A is an SEM image indicating crystallized GeTe line pattern and Nanoprobe configuration used for I-V measurements. FIG. 8B shows measured I-V characteristics acquired when contacting the crystallized line (squares) and the amorphous field (circles). The inset is an enlarged plot of I-V acquired on the crystallized line.

FIG. 9 is an NSOM-measured transmission at 532 nm and calculated crystallization fraction of ˜1 μm×1 μm squares of GeTe patterned at varying probe powers.

FIG. 10A is an NSOM image of transmitted 532 nm light through a zigzag pattern that was generated in a single-pass scan, from bottom left to top right, at a tip power of 7.95 mW. The probe speed was increased for each vertical line segment, as indicated. FIG. 10B is an NSOM profile along the trace in FIG. 10A highlighting regions of GeTe crystallized at different probe speeds. Faster probe speeds results in more transmission through the film, indicating a smaller volume of crystallized material.

### DETAILED DESCRIPTION OF THE INVENTION

A heated nanoscale probe, such as a metallic AFM tip, is brought into contact with the PCM surface. During contact, heat is transferred from the probe to the surface, increasing the temperature of the PCM material in the immediate vicinity of the tip. If the surface temperature exceeds the PCM crystallization temperature, the tip will induce a local phase change from amorphous to crystalline state, resulting in dramatic changes in electrical, optical, and volumetric properties of the crystallized region, while leaving the properties of the surrounding amorphous PCM material unchanged. The width and depth of the patterned region is dependent upon the dimension and temperature of the heated probe, the speed at which the probe is moved across the surface, and the effectiveness of thermal transport within the film and at the surface-probe junction. Smaller, cooler probes and faster writing result in narrower patterned linewidths, with linewidths of ˜200 nm and topographic features <30 nm in depth achieved without optimization. The pattern can be effectively erased by re-amorphizing the crystallized region by heating the region above its melting temperature and quenching, thereby allowing for re-writability. The writing process works on an amorphous PCM surface regardless of substrate material or film thickness. Potential applications include, but are not limited to, rewritable arrays of resonators, with dimension (and thus resonance frequency) which can be changed on demand, rewritable spiral inductors, rewritable conductive wires to optimize circuits and other nanoscale devices.

The PCM can be a chalcogenide material. Commonly used chalcogenide PCMs include GeTe and GeTe-based alloys, including GeSbTe.

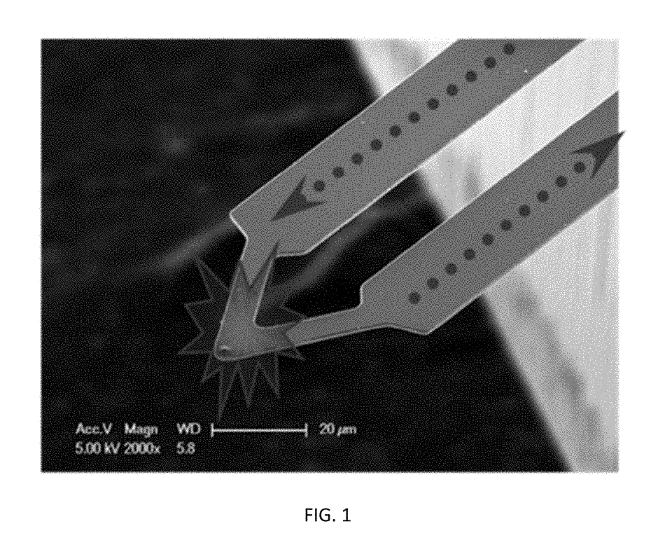

FIG. 1 shows the heated probe. Heating is controlled by passing a current through the cantilevers. The maximum probe temperature of currently-available probes is 1200° C.; however higher temperature probes would also be applicable to this approach.

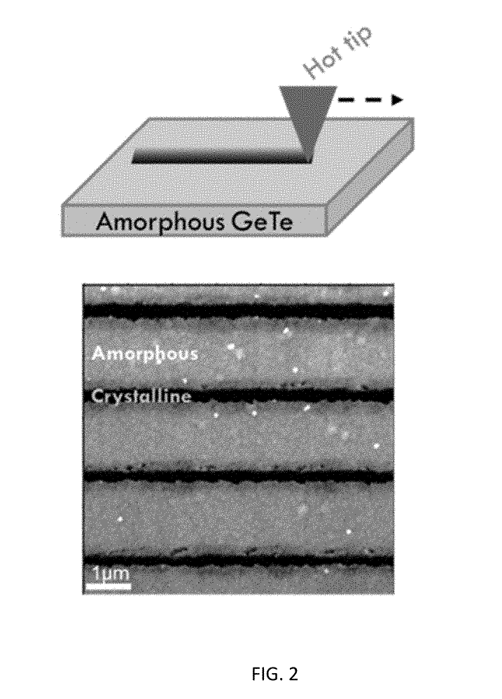

FIG. 2 shows patterning of a GeTe surface using the heated probe. Any GeTe surface, regardless of substrate properties, can be patterned using the heated probe with nanoscale precision over large areas.

### Example

Described herein is the nanopatterning of GeTe thin films by inducing localized crystallization via a fast-scanning heated-tip AFM. The binary chalcogenide GeTe, which has a low crystalline-phase electrical resistivity and a relatively high crystallization temperature (˜180° C.), was used; although, the approach will work for many PCM chalcogenide alloys. Either tip power or tip temperature may be used as a variable. Tip power can be actually measured, while tip temperature is estimated.

The GeTe thin films were prepared by pulsed DC sputtering from compound stoichiometric targets at 100 W in a 5 mTorr Argon atmosphere at room temperature, resulting in the deposition of an amorphous GeTe layer. Film thickness and substrate could be varied, but most work in this example was performed on films ˜620 nm thick and deposited onto fused silica substrates, unless otherwise noted. Following deposition, GeTe composition and structure were probed using a Thermoscientific K-alpha x-ray photoelectron spectroscopy (XPS) system and a Rigaku Smartlab X-ray diffraction (XRD) instrument, respectively. Variable temperature XRD was performed by pairing the Rigaku instrument with an Anton Paar DHS 1100 domed heated stage to evaluate film structure during a stepped anneal, allowing precise determination of the GeTe crystallization temperature. Four-point probe measurements characterized the conductivity of the amorphous and crystalline films. Nanopatterning of the GeTe was performed using an Asylum Cypher AFM with a heatable tip in contact mode, with tip temperature and write speed varied to tune the resultant pattern properties. Patterned regions were subsequently imaged via tapping-mode AFM, taking advantage of the volumetric contraction associated with the amorphous-to-crystalline phase transition to identify regions of crystallized GeTe, which appear as surface depressions. Cross-sections of the patterned regions were milled using a focused ion beam (FIB) instrument and observed via a transmission electron microscope (TEM), while the electrical properties of the patterned regions were probed.

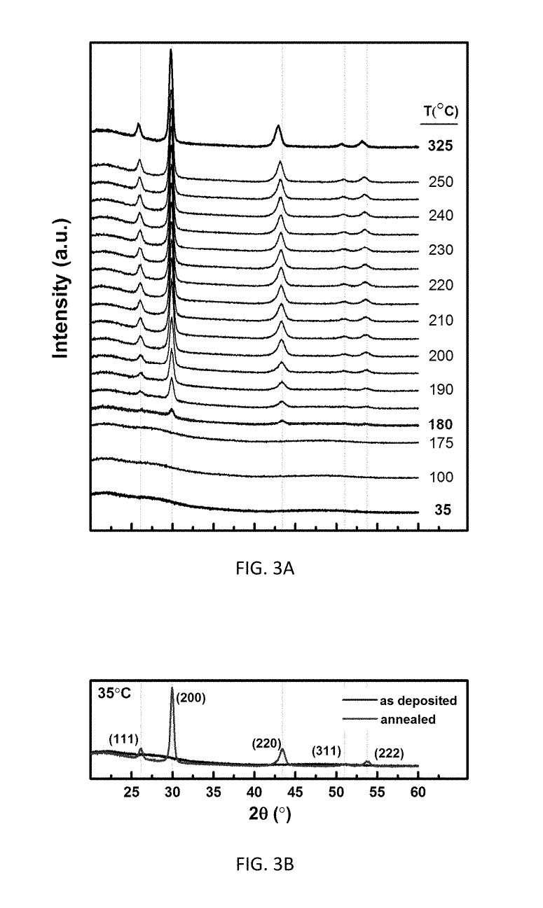

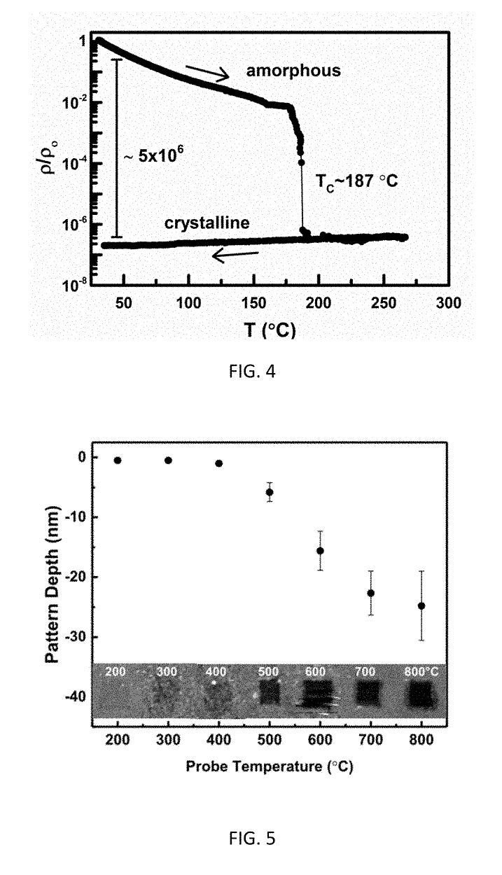

FIG. 3A shows the XRD spectra of the deposited GeTe film as a function of temperature from 35° C. to 325° C.; the temperature was increased in 5° C. steps in the vicinity of the transition, from 170° C. to 180° C., to obtain finer temperature resolution. The lack of structure in the initial 35° C. spectra in FIG. 3A indicates the GeTe film is amorphous as-deposited. Upon heating, the film begins to crystallize near 180° C., in good agreement with other literature reports (Zhou et al., Scientific Reports 5 (2015); King et al., Journal of Vacuum Science & Technology B 32 (2014); Ren et al., Applied Physics Letters 103 (2013); and Kim et al., Japanese Journal of Applied Physics, 50, 101802, 4 pp. (2011)). The reduction in peak full-width half maximum and leftward peak shift as the sample is heated further to 325° C. are indicative of crystal grain growth and temperature-induced lattice expansion, respectively. As shown in FIG. 3B, the crystallinity is preserved when the sample is returned to 35° C. Though a rhombohedral structure is often reported for crystalline GeTe at ambient conditions (Chopra et al., Journal of Applied Physics, 40, 4171 (1969); Kim et al., Journal of Electronic Materials, 42, 78 (2013); and Gourvest et al., ECS Journal of Solid State Science and Technology, 1, Q119 (2012)), like other authors (Kim et al., Journal of Electronic Materials, 42, 78 (2013); Tong et al., Applied Physics Letters, 97 (2010); and Kim et al., Journal of Applied Physics, 49 (2010)) only the fcc rock-salt (NaCl) phase was observed, with all peaks well accounted for by the space group Fm-3m configuration using a lattice parameter of 5.917 Å. The presence of the cubic, as opposed to rhombohedral, crystal structure may be related to the deposition conditions used, the slightly Ge-rich stoichiometry of the films, or the kinetics of the crystallization process. Four-point probe resistivity measurements of the film as a function of temperature are plotted in FIG. 4, where the amorphous-to-crystalline transition is indicated by a precipitous drop in film resistivity that persists when the film is cooled. The transition occurs at approximately 186° C., in good agreement with the crystallization temperature observed via XRD. The four-point probe measurements indicate that the resistance ratio between amorphous and crystalline phases of the GeTe film is 5×10⁶ at 35° C.

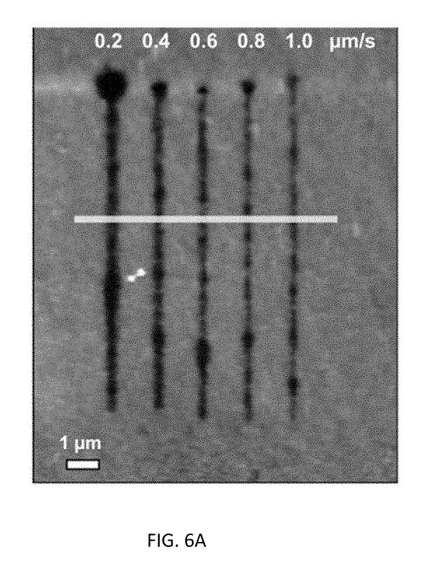

While blanket anneals crystallize the entire amorphous GeTe film, by using a heatable AFM probe as a confined source of thermal energy, the phase transition and pattern arbitrary crystalline regions can be localized with nanometer-scale precision. Crystalline square patterns 1 μm on each side were generated using an AFM probe whose temperature was nominally held from 200° C. to 800° C., with the tip scanned at a speed of 500 nm/s and rastered over the area for ˜20 minutes. AFM images of the patterned squares depicted in the inset of FIG. 5 show that, at nominal probe temperatures 500° C. and above, the rastering induced a local surface depression, indicative of the volume contraction associated with the amorphous-to-crystalline phase transition. Depth measurements of these squares (FIG. 5) show that relief features of up to 25 nm could be patterned using these scan conditions, with the depth of the depression, and thus the volume of GeTe crystallized, controlled by varying the probe temperature. The threshold observed for the onset of crystallization suggests that a nominal tip temperature of 500° C. corresponds to a surface temperature of ˜180° C., with the difference in probe and surface temperatures attributable to the significant thermal resistance of the tip-surface contact. The minimal (0.5-1.0 nm) depressions at nominal probe temperatures less than 500° C. arise from mechanical abrasion; the loading force on the probe during patterning was 20-30 N/m and was held constant for all the patterning runs.

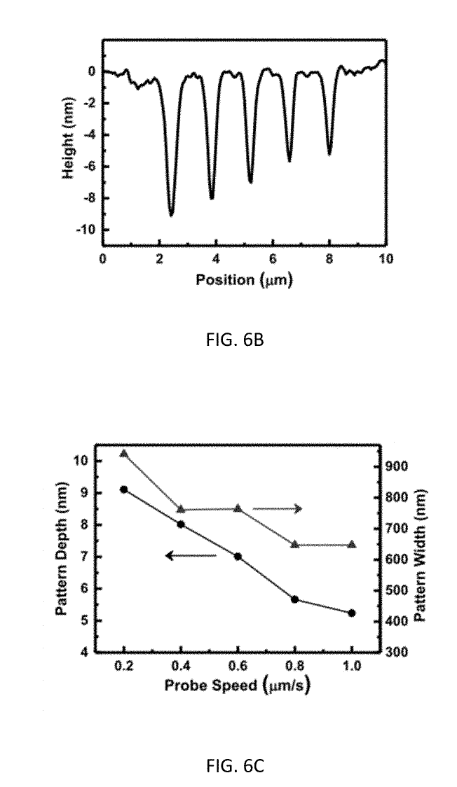

To evaluate the impact of tip speed on pattern depth and width, multiple lines were generated at a fixed probe temperature of 700° C. (approximate surface temperature of 230° C., as estimated from thermal diffusion properties of the film and tip) while the heated probe scanned a single line at rates ranging from 0.2 μm/s to 1.0 μm/s, with the resulting AFM topograph and line profile shown in FIG. 6A and FIG. 6B, respectively. FIG. 6C plots the measured depth and width (measured at the surface) of the patterned lines. Slower writing speeds generated deeper and wider line profiles, indicating a larger volume of the GeTe has been crystallized due to the increased heat diffusion enabled by the increased probe contact time. The line width and depth profile reach a minimum of ˜650 nm wide and 5.3 nm deep at a tip speed of approximately 0.8 μm/s, with no increase observed for faster tip speeds. As shown in FIG. 5, deeper patterns, and thus a greater crystalline GeTe volume, can be achieved by repeatedly scanning a given region. The phase transition occurs both in the contact area of the heated tip, as well as the adjacent area due to thermal diffusion, so that the lateral and depth resolution is limited by not only the radius of curvature (˜100 nm) of the heated tip, but also by the heat transport within the amorphous GeTe film.

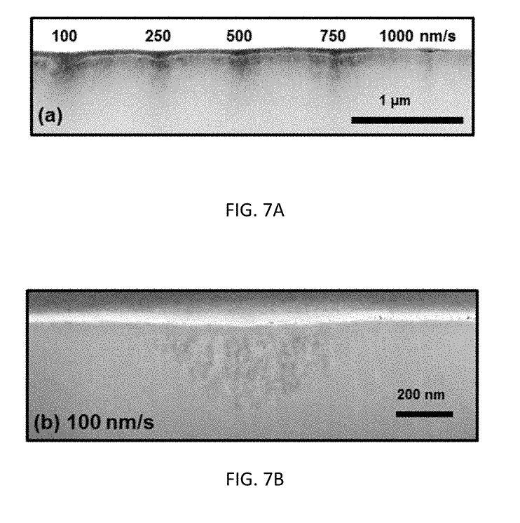

To probe the extent of GeTe crystallization induced by the heated tip, cross-sectional lamella of a series of lines patterned at a probe power of 6.83 mW and write speeds varying from 100 to 1000 nm/s were investigated using transmission electron microscopy (TEM). FIG. 7A and FIG. 7B show the resultant bright-field TEM micrographs, where the crystallographic change in the subsurface region beneath each pattern is evident from the image contrast. In FIG. 7A, the surface depressions detected via AFM are apparent, surrounded by mottled, variable contrast regions whose extent into the subsurface decreases as the write speed is increased from 100 nm/s to 1000 nm/s (left to right), indicating the smaller volume of GeTe crystallized using larger probe velocities. FIG. 7B shows a higher-magnification micrograph of the region beneath a separate line patterned at 100 nm/s and 6.83 mW. The crystallized region, demarcated by the mottled contrast, extends ˜300 nm into the film, with a width of ˜720 nm.

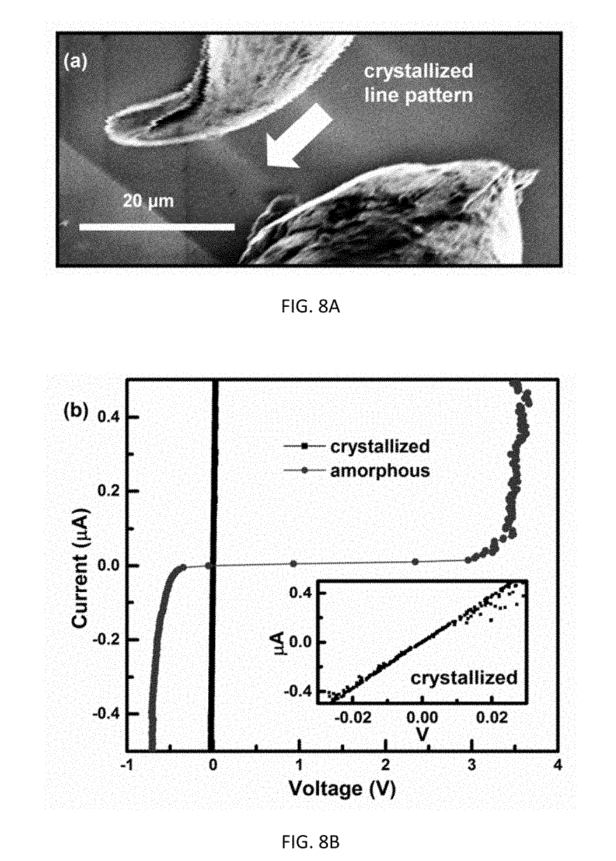

As crystalline GeTe is considerably more conductive than amorphous GeTe, significant electrical contrast between the patterned regions and the surrounding amorphous field are expected. Electrical measurements of crystallized and amorphous regions were obtained using a Nanoprobe instrument with two independently controlled scanning tunneling microscopy (STM) tips, where an in situ high-resolution scanning electron microscope (SEM) enables positioning of the tips with sub-micron precision. FIG. 8A shows an SEM image of a 15 μm long crystallized GeTe line (6.83 mW, 100 nm/s) contacted by two tungsten STM tips. The enhanced electrical conductivity of the crystalline GeTe provides a bright SEM contrast when compared to the surrounding, insulating amorphous field. Current-voltage (I-V) measurements from the crystallized line are shown in FIG. 8B, along with comparable data acquired on the adjacent amorphous film. The highly non-linear I-V curve obtained on the amorphous GeTe (circles) signifies an insulating film, with negligible current measured at biases <3 V. Alternatively, the crystallized GeTe line is conducting, exhibiting linear Ohmic conduction across the full range measured (FIG. 8B, inset) and behaving as an embedded nanowire, with an estimated metallic resistance of ˜55 kΩ, which includes the contact resistance between the crystalline GeTe and the tungsten probes.

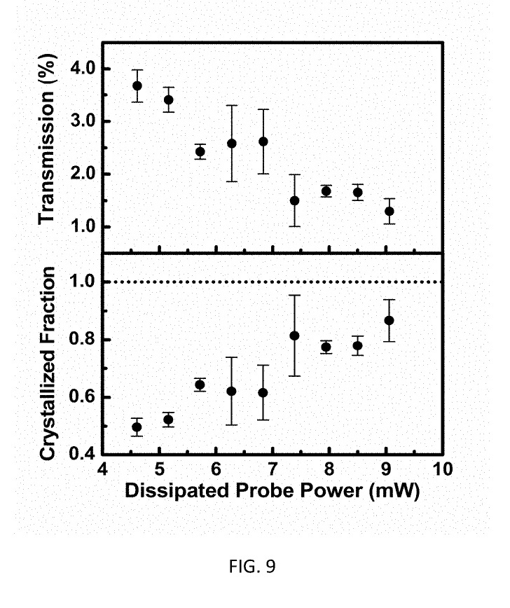

In addition to contrasting electronic behavior, the two phases of GeTe possess different optical responses, with amorphous GeTe transparent and crystalline GeTe absorptive across much of the visible spectrum. To optically characterize the patterned regions, near-field scanning optical microscopy (NSOM) was used to measure transmission at 532 nm through GeTe films treated with a heated tip. To limit loss through the sample, all optical measurements were performed on thinner (˜62 nm) films of GeTe deposited onto fused silica substrates. The patterns studied were ˜1 μm×1 μm squares written by a rastered probe at different powers (4.61 mW-9.06 mW), as well as single-pass lines written at tip speeds ranging from 200 to 1000 nm/s (7.95 mW). Regions treated with different dissipated probe powers, and thus different surface temperatures, exhibited a linear reduction in transmission with increased treatment temperature (FIG. 9), corresponding to a more complete phase change induced with higher temperatures, in agreement with XRD and resistivity data. Furthermore, with knowledge of the extinction coefficients, kₐ and k_{c}, of the amorphous and crystalline phases, respectively (measured via spectral ellipsometry), the fraction of film crystallized for each of the thermally treated regions may be extracted based on their transmissivity. Assuming the partially crystallized film can be treated as a two-layer stack of a crystallized layer atop an amorphous layer, the absorption due to each layer may be summed giving a total transmission of

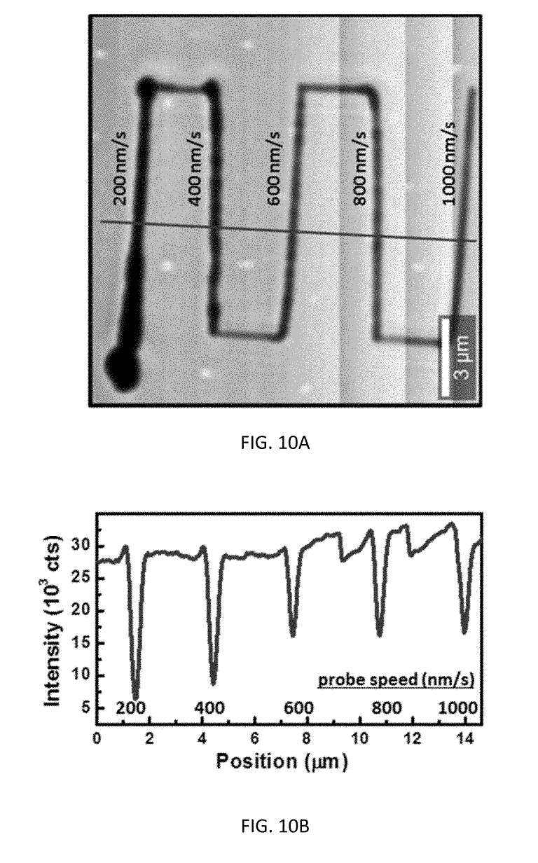

T=e^{-4πv[k}^{ₐ}^{L(1-p)+k}^{_{c}}^{L(p)]} (1)

where v is the light frequency (18797 cm⁻¹ corresponding to the 532 nm laser), L is the total film thickness, and P is the fraction of film crystallized. This crystallization fraction was extracted and plotted in FIG. 9B. These results show significant crystallization (˜50%) at a tip power of 4.61 mW and >80% transformation at dissipated probe powers equal to or greater than 7.39 mW. The extracted crystallized film fraction is sensitive to the extinction coefficient values and that a 10% reduction in the k_{c} value would increase the calculated crystallization fraction at 7.39 mW to ˜100%. Probing regions patterned with a single-pass line scan at varying speeds (FIGS. 10A and 10B) yielded NSOM-measured linewidths of optically-distinct regions down to ˜290 nm (FWHM) with crystallization fractions of 27%.

GeTe PCM films were locally patterned with nanometer-scale precision through heated-tip AFM lithography. Conductive channels of crystalline GeTe were written in amorphous thin films, with the width, depth, and volume of crystalline material varied by controlling the tip temperature and write-speed. Cross-sectional TEM imaging verified the crystallinity of the transformed volume, while KPFM provided evidence of the local enhancement of conductivity in the patterned regions. This approach to nanopatterning is extensible to a wide range of other chalcogenide-based PCM alloys and, when coupled with an anneal-quench process for re-amorphization, enables the realization of non-volatile, nanoscale rewritable conductive pathways without the need for special substrates or laser optics.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A nanopatterned phase change material made by the method comprising:
heating a probe;
contacting the heated probe with a surface of a phase change material thereby inducing a local phase change at the contacted surface, wherein the phase change material comprises a chalcogenide; and
moving the heated probe across the surface of the phase change material resulting in a patterned region.

2. The nanopatterned phase change material of claim 1, wherein the probe is a nanoscale probe.

3. The nanopatterned phase change material of claim 1, wherein the probe is an atomic force microscopy tip.

4. The nanopatterned phase change material of claim 1, wherein heating the probe comprises passing a current through cantilevers on the probe.

5. The nanopatterned phase change material of claim 1, wherein the phase change material comprises GeTe or a GeTe-based alloy.

6. The nanopatterned phase change material of claim 1, wherein the phase change material comprises a GeSbTe compound.

7. The nanopatterned phase change material of claim 1, wherein the width and depth of the patterned region are controlled by adjusting the dimension of the probe, the temperature to which the probe is heated, the speed at which the probe is moved across the surface of the phase change material, or any combination thereof.

8. The nanopatterned phase change material of claim 1, additionally comprising preparing the phase change material for re-writing by heating the patterned region above its melting temperature and quenching.
